(19) United States
(12) Patent Application Publication
(10) Pub. No.: US 2007/0002607 A1
(43) Pub. Date: Jan. 4, 2007

(54) Memory circuit

(76) Inventors: Muhammad M. Khellah, Tigard, OR (US); Dinesh Somasekhar, Portland, OR (US); Yibin Ye, Portland, OR (US); Vivek K. De, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/172,078

(22) Filed: Jun. 29, 2005

(51) Int. Cl. G11C 11/00

(52) U.S. Cl. 365/154

(57) ABSTRACT

In some embodiments, a memory array is provided comprising columns of SRAM bit cells, the columns each comprising a bit line and a sense amplifier coupled to the bit line, the sense amplifier to maintain a state in a selected cell of its bit line during a read operation. Other embodiments are disclosed herein.

### TECHNICAL FIELD

Embodiments disclosed herein relate generally to integrated circuit (“IC”) devices and in particular to memory circuits.

### BACKGROUND

Memory arrays formed from static random access memory (“SRAM”) cells are commonly used in many different applications. Such arrays are typically configured into multiple columns of cells with each column of cells sharing a common bit line. For example, with so-called “6T” SRAM cells, which have a pair of complementary storage nodes, a common, complementary bit line pair is typically utilized. It is usually controllably coupled (e.g., through gate or access transistors) to a relatively large number of cells in a column. When a cell is to be read, the bit line pair is charged to a High level during a precharge state. Next, during an evaluate state, a selected cell to be read is activated (coupled to the bit line pair with its gate transistors turned on) causing one of its bit lines to discharge into the Low node of the selected cell. Unfortunately, in some cases, the bit line discharges in a way that causes the cell to be improperly read.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic diagram of a conventional memory array circuit.

FIG. 2 is a schematic diagram of a conventional bit cell column, which may be used in the memory array circuit of FIG. 1.

FIG. 3 is a schematic diagram of a conventional 6T SRAM bit cell circuit, which may be used in the memory array circuit of FIG. 1.

FIG. 4 is a schematic diagram of a memory array circuit according to some embodiments of the present invention.

FIG. 5 is a schematic diagram of an embodiment of a bit cell column, which may be used in the memory array circuit of FIG. 4.

FIG. 6 is a timing diagram for one embodiment of a read operation for the memory array circuit of FIG. 4.

FIG. 7 is a block diagram of a system having a processor chip with a memory array circuit according to some embodiments of the present invention.

### DETAILED DESCRIPTION

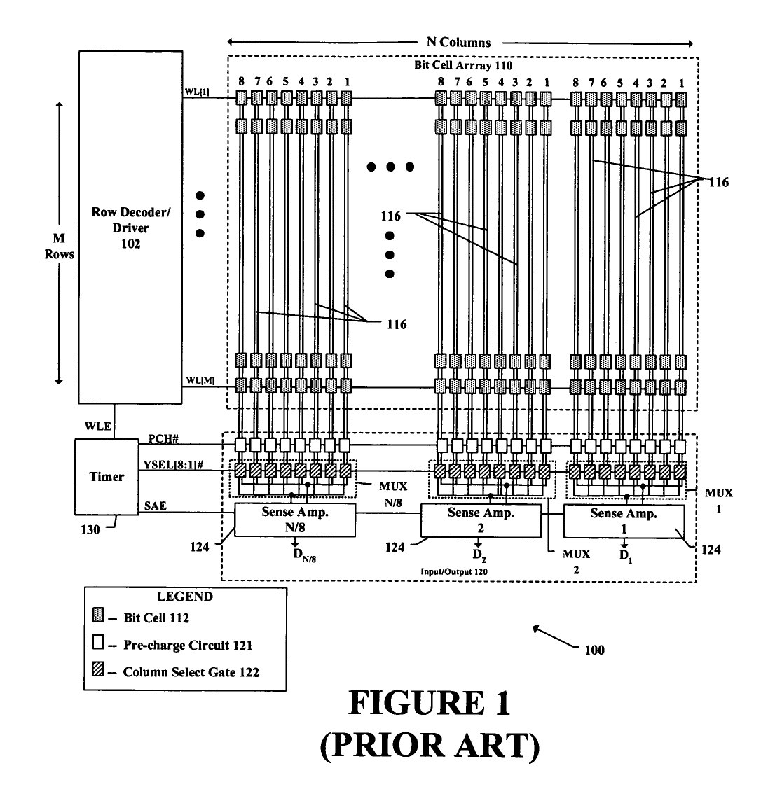

FIG. 1 shows a conventional memory array circuit 100 having M rows and N columns of memory cells. Memory array circuit 100 includes a row decoder/driver circuit 102, a bit cell array 110, an input/output circuit 120, and a timer circuit 130. The bit cell array 110 includes M rows of bit cells 112 configured into N different columns with each column having a bit line 116 and M associated bit cells each controllably coupled to the bit line 116.

(Note that the depicted bit line 116 actually comprises two, complementary lines. As used herein, a bit line may comprise one or more actual lines in cooperation with an implemented bit cell and/or bit cell array configuration. In addition, as used herein, the term: “controllably coupled” means configured to be coupled, decoupled or coupled/decoupled to an adjustable degree based upon the state(s) of one or more control signals. Any suitable device or device combination, e.g., implementing a gate, switch, multiplexer, supply switch, or the like, may be used to controllably couple a circuit element to another circuit element. For example, a bit cell may be controllably coupled to a bit line through access transistors.)

The row decoder/driver 102 has word line outputs (WL[1] to WL[M]) applied, respectively, to the 1 through M rows of bit cells 112. When a cell is to be read, row decoder/driver 102 asserts (High) the word line output signal (WL[i]) that is applied to the row containing the bit cell(s) 112 to be read, and the other (non-selected) word line output signals are negated (Low).

The input/output circuit has precharge circuits 121, column select gates 122 and sense amplifiers 124. The precharge circuits 121 are each coupled to an associated bit line pair 116 for controllably charging the bit line pair (e.g., during a precharge state). The column select gates 122 are disposed as multiplexers. In the depicted figure, they are grouped into N/8, 8:1 multiplexers. Each column select gate is interposed between a bit cell column and an associated sense amplifier 124 to controllably couple its associated bit cell column to its associated sense amplifier when a bit cell in the column is to be accessed. (Note that in this depiction, the column select gates 122 and sense amplifiers 124 are used for read operations. Separate sense amplifiers and column select gates, not shown, may be used for write operations.)

In the depicted circuit, column interleaving is employed. One sense amplifier 124 is used for eight separate columns multiplexed to it through column select gates 122. Thus, with this configuration, the N bit columns define eight separate, N/8-bit words for each row. For example, with a 256 by 256 bit cell array, 32 separate sense amplifiers 124 output eight separate 32-bit (D₃₂ to D₁) words for each row. (Of course, any suitable sized array and/or word may be employed.)

The timer 130 has a word-line enable (WLE) output coupled to the row decoder/driver 102. It also has a precharge output signal (PCH#) coupled to the precharge circuits 121, column select output signals (YSEL[7:0]#) coupled to corresponding column select gates 122, and a sense amplifier enable (SAE) output signal coupled to the sense amplifiers 124. It controls these signals to implement a read operation for a selected row (1 to M) and word (1 to 8) of bit cells 112.

On a read operation, the bit line pairs 116 are charged High during a precharge state. The precharge (PCH#) signal is asserted (Low) to turn on the precharge circuits 121, the eight column select (YSEL[8:1]#) signals are negated (High) to turn off the column select gates 122, and the M word-line signals (WL[1] to WL[M]) are negated (Low) to de-activate the bit cells 112 (i.e., de-couple them from the bit line pairs 116). Thereafter, during an evaluate state, a selected one of the word-line signals (corresponding to a row to be read) is asserted (High) thereby causing one of the bit lines from each bit line pair 116 to discharge into an associated bit cell 112 in the selected row. This is done by negating (High) the precharge signal (PCH#) and asserting (High) a selected one of the word line signals (WL[1] to WL[M]) to activate the cells 112 in the selected row. At the same time, a selected one of the column select signals (YSEL[8:1]) is output by the timer to couple a selected one of the eight bit line pairs, associated with each sense amplifier 124, to its associated sense amplifier 124. That is, in the depicted figure, one of every eight bit line pairs 116 is coupled through to its corresponding (or associated) sense amplifier 124. Note that in some embodiments, when a read operation occurs, one or more selected columns (one of columns 1 to 8 in each group of 8) are “read”, but the other columns may still be dummy read. That is, even though their bit lines are not coupled to a sense amplifier, they are still precharged and discharged into a cell on a selected word line.

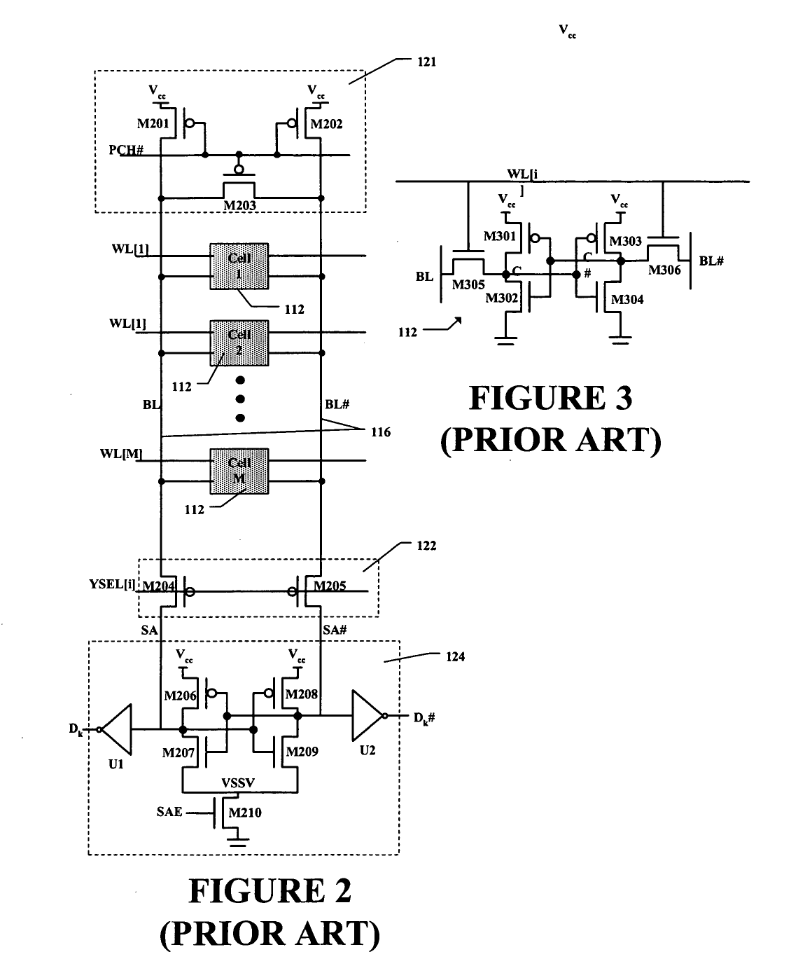

With reference to FIG. 2, one embodiment of a cell column that may be used in cell array 110 is depicted. In this figure, circuits for implementing a precharge circuit 121, a column select gate 122, and a sense amplifier 124 are shown. (A circuit for implementing a bit cell 112 is depicted in FIG. 3.)

The depicted precharge circuit 121 is coupled to the bit lines (BL, BL#) to charge them to a High level during a precharge state. (As used herein, a “precharge circuit” refers to any suitable device or device combination configured to charge a bit line or bit line pair to a suitable High level.) Precharge circuit 121 comprises p-type field-effect-transistors (“PFET”) transistors M201 to M203 configured, as shown, between a suitable High-level precharge voltage (e.g., V_{cc}) and the bit line pair (BL and BL#) 116. When the precharge signal (PCH#) is asserted (Low), the precharge circuit transistors M201 to M203 turn on and couple the precharge voltage (V_{cc}) to the pair 116 of bit lines (BL, BL#) to charge them to a High level and to equalize them with one another. (Note that in this figure, the precharge circuit 121 is depicted at the top of the bit line pair 116 for ease of representation. While it could physically be located here, or anywhere along the bit line pair for that matter, in the depicted array of FIG. 1, it is shown as part of the input/output block 120 because it is physically located more proximal to the timer 130 and input/output 120 devices to reduce signal path lengths.)

The depicted column select gate 122 is disposed in each bit cell column and comprises PFET transistors M204, M205 connected between an associated bit line pair 116 and a sense amplifier 124. (As used herein, a “column select gate” refers to any suitable device or device combination configurable to controllably couple/decouple a bit line or a bit line pair to/from a sense amplifier.) When the column select signal (YSEL[i]) corresponding to a column select gate 122 is asserted (Low), transistors M204, M205 turn on and couple the bit line pair 116 to the corresponding sense amplifier 124. Conversely, when the signal is negated (High), the bit line pair 116 is effectively decoupled from the sense amplifier 124.

The depicted sense amplifier 124 comprises pull-up PFET transistors M206, M208, pull-down n-type field-effect-transistor (“NFET”) transistors M207, M209, a virtual ground providing NFET transistor M210, and inverters U1, U2. The pull-up and pull-down transistors (M206 to M209) are coupled to one another in a cross-coupled inverter pair configuration with sense nodes at S and S# and a virtual ground node (VSSV) at the drain of NFET transistor M210. The sense nodes (S, S#) are connected to column select gate 122 to be controllably coupled to the BL and BL# nodes, respectively, of a bit line pair 116. They also are respective inputs to inverters U1 and U2, with the output (Dₖ) of inverter U1 functioning as the indicated output for a sense amplifier 124 in FIG. 1.

During an evaluate state, the sense amplifier enable (SAE) signal is asserted (High), which turns on transistor M210 thereby activating the sense amplifier 124. Based on the content of a selected bit cell 112, either the BL or BL# node will start dropping and develop a small differential voltage on the bit line pair 116. This relatively small voltage is “interpreted” by the sense amplifier's cross-coupled inverter pair (M206 to M209) and buffered into a stable, readable output from inverter U1 at Dₖ.

With reference to FIG. 3, a bit cell 112 is depicted. (As used herein, a “bit cell” refers to any suitable device or device combination for implementing a memory cell coupled to a dischargeable bit line or bit line pair.) The depicted bit cell 112 is a so-called 6T SRAM cell, which is a complementary-output (outputs with complementary values) static random access memory (“SRAM”) cell. It comprises pull-up, PFET transistors M301, M303, pull-down, NFET transistors M302, M304, access (or gate) NFET transistors M305, M306, a word-line node (WL), and bit line pair nodes (BL, BL#). The pull-up and pull-down transistors M301 to M304 are coupled to form a cross-coupled inverter pair having internal, complementary storage nodes (C and C#). The complementary storage nodes (C, C#) are controllably coupled, respectively, to the bit line nodes (BL, BL#) through gate transistors M305 and M306. Thus, during a precharge state when both bit line nodes (BL, BL#) are charged High, a Low level will be at either the C or C# storage node with a High at the other storage node. When the word-line node (WL) is asserted (High), gate transistors M305 and M306 turn on thereby discharging the bit line node (BL or BL#) that is coupled to the Low storage node (C or C#).

Unfortunately, read operations can be unstable due, among other things, to a noise spike imposed on the Low bit cell storage node (C or C#) when a bit line is discharged into it. As the selected word-line is asserted causing BL or BL# to discharge into the selected bit cell, a noise bump may be imposed at its Low storage node due to voltage division between the bit cells' “Low-side” gate and pull-down transistors. The resistance of the pull-down transistor relative to that of the gate transistor is commonly referred to as cell ratio. The lower the cell ratio, the smaller the bump on the storage node resulting in a more stable read operation on the cell. Accordingly, some prior art solutions have relied on cells with sufficiently low cell ratios (i.e., with pull-down transistors having sufficiently lower resistances relative to their associated gate transistors) to achieve sufficient read stability. Other solutions have involved applying a negative voltage as the ground to the pull-down transistors in the cell during an evaluate state.

In this disclosure, a novel approach is presented. The basic idea is to write back to the cell upon a read operation to correct for or prevent possible flipping. With such an approach, noise events on a Low storage node of a selected cell can be tolerated and thus, in some embodiments, even unity ratio cells may be used. (It should be recognized that embodiments of the invention do not preclude the use of conventional approaches, including those mentioned above, in combination with novel techniques disclosed herein.)

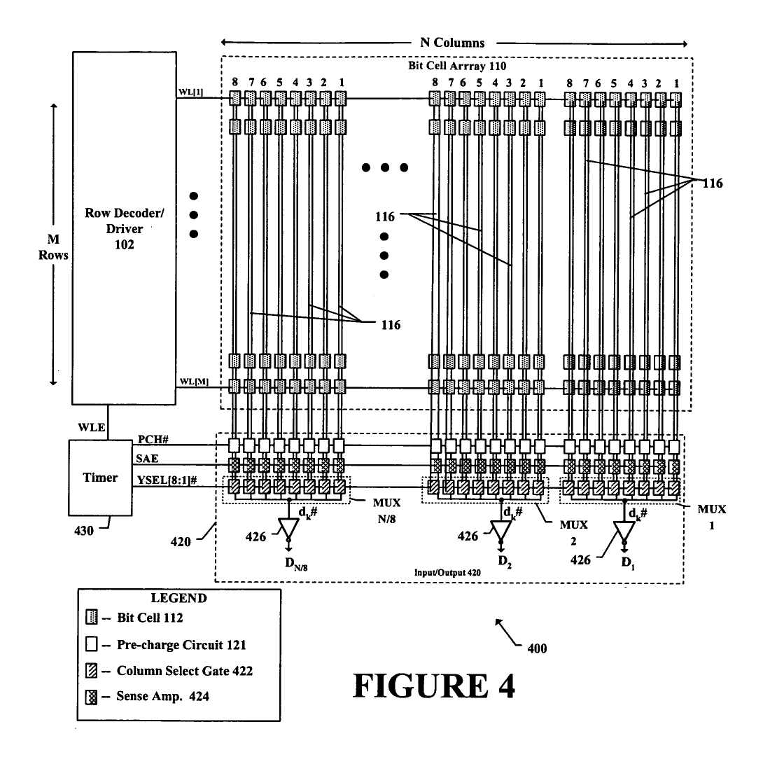

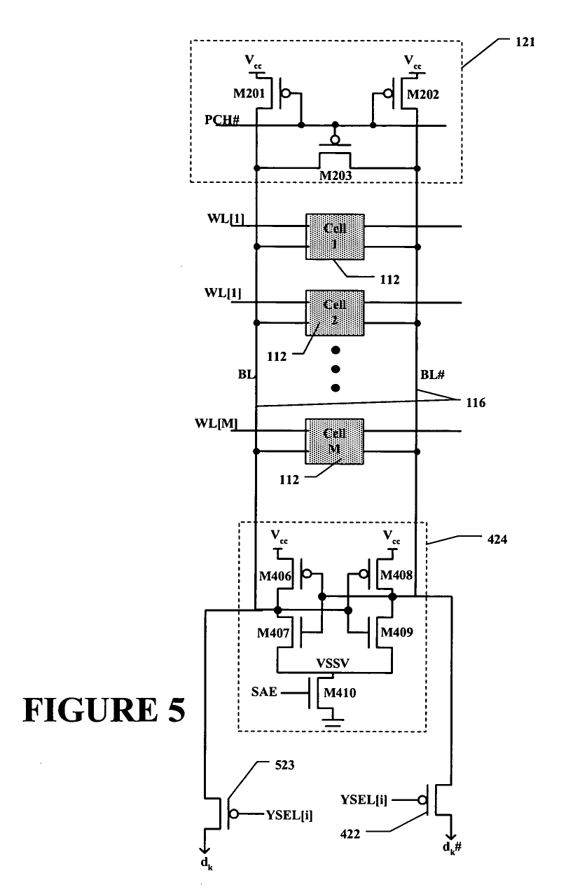

With reference to FIGS. 4 and 5, a memory array 400 with write-back capability is depicted. FIG. 4 shows a memory array 400, and FIG. 5 shows from memory array 400 a bit cell column coupled to portions of its input/output circuitry. The memory array 400 generally comprises a row decoder/driver 102, a bit cell array 110, input/output circuitry 420, and a timer circuit 430.

The row decoder 102 and bit cell array 110 may be implemented as previously discussed. The depicted input/output circuitry 420 comprises precharge circuits 121, column select gates 422, sense amplifiers 424, and output drivers 426. The precharge circuits 121 and column select gates 422 may be implemented as previously discussed, except that a column select gate 422 may be implemented with a single transistor (instead of a transistor pair) disposed between a bit line 116 and an output driver 426. That is, groups of column select gates 422 are disposed together to multiplex groups of bit lines (groups of 8 in the depicted embodiment) to an associated output driver 426. (As shown in FIG. 5, a “dummy” column select transistor 523, coupled to a non-utilized output of a sense amp, may also be included for load balancing purposes.)

The input/output circuitry 420 includes a separate sense amplifier 424 coupled to each bit line. The sense amplifiers 424 serve to not only output the state of a read bit cell, but also, they write back or maintain cell states (or values) for cells in an activated word line during a read operation. A sense amplifier may comprise any circuit or circuit combination that can perform one or both of these functions. In the depicted embodiment, sense amplifier 424 performs both functions. It is formed from a cross-coupled inverter pair with a transistor M410 to provide a virtual ground (VSSV) for controllably enabling/disabling the sense amplifier 424. Unlike some sense amplifier designs, an implemented sense amplifier 424 does not require separate precharge circuitry since it is coupled to a precharge circuit 121 through a bit line 116. In addition, it may not need output drivers such as with the depicted embodiment where shared output drivers 426 are used. Moreover, in some embodiments, it need not be as large as when used in a conventional sense amplifier configuration. That is, since the sense amp is per bit line pair (not shared as in FIG. 1), a smaller sense amplifier can be used. (Eliminating select devices before a sense amplifier also helps in reducing its size.) However, it should still be able to suitably sense a state on the bit line, e.g., a small differential voltage such as 50 mV or so depending on a particular implementation.

The output drivers 426 may or may not be required. In the depicted embodiment, they are controllably coupled through column select gates 422 to a group of bit lines 116 and accordingly to the effective sense amplifier outputs. Thus, they allow for smaller sense amplifiers 424 without requiring output drive capability. In the depicted circuit, they are implemented with a conventional back-to-back coupled PMOS/NMOS inverter circuit.

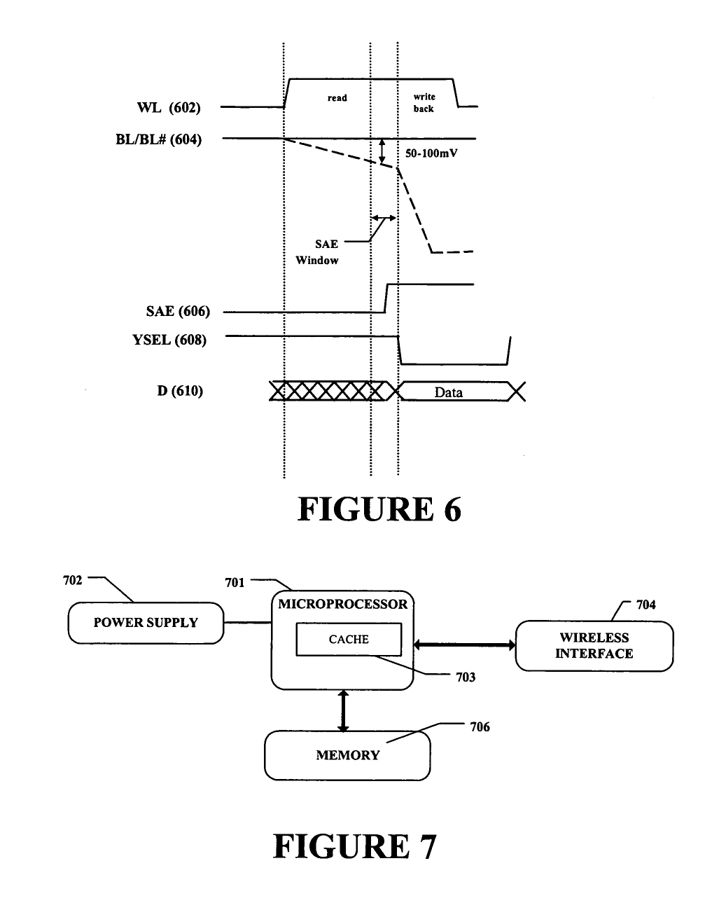

The timer 430 (which may be implemented with any suitable circuitry) is coupled to the row decoder 102 and input/output circuitry 420 to control at least read operations. (A timing diagram in accordance with some read operation embodiments is shown at FIG. 6.) It has a word line enable (WLE) signal coupled to the row decoder/driver 102 and precharge (PCH#), sense amplifier enable (SAE), and column select (YSEL[8:1]#) signals coupled to the input/output circuitry 420. The PCH# signal, when asserted (Low), causes the precharge circuits 121 to precharge the bit lines 116. The SAE signal, when asserted (High), causes the sense amplifiers 424 to be enabled (turn on) and thus to catch and hold (or flip back, if flipped) the value in the selected cell on its associated bit line 116. Finally, when a selected one of the YSEL[8:1]# signals is asserted, the corresponding column select gates 422 (e.g., one of 1 through 8 in each group) turn on and coupled a selected bit lines to associated output drivers 426.

Note that in the depicted embodiment, during a read operation, cell(s) to be read from are read and those not to be read are dummy read. This means that bit lines 116 from unselected columns are precharged and thus, each cell in a selected row is evaluated (discharges current into a low-side node) even if it is not selected to be read. Thus, during a read operation, each cell in a selected row is susceptible of flipping. Fortunately, when the SAE signal is asserted, a sense amp 424 in each column turns on thereby maintaining cell state for each cell in a selected row, even those from which data is not necessarily read.

With reference to FIG. 6, a timing diagram showing relevant portions of signals for a read operation is illustrated. Depicted are portions of a word line signal (WL) 602, bit line signal (BL/BL#) 604, sense amp enable (SAE) signal 606, column select signal (YSEL) 608, and data signal (D) 610. These signals correspond to the indicated signals in FIG. 4 with the bit line signal corresponding to the differential voltage across a selected column, the column select signal corresponding to a column select signal applied to the column select gate on the selected column, and the data signal (D) corresponding to the output of the output driver associated with the selected column.

The read operation begins with the bit lines being precharged (precharge signal is asserted, not shown). Next, the word line signal is asserted (High). This causes a differential voltage to be applied across the lines of the bit line (BL/BL#). The SAE signal 606 is then asserted at some time within a suitable window when the bit line signal is large enough for the sense amp to catch (or read) it but small enough (or within a small enough amount of time from when the signal is large enough to read) to be able to hold or flip back the value in the cell. In the timing diagram, this window is labeled “SAE Window” and occurs when the differential voltage across the bit line from about 50 to 100 mV. The YSEL signal 608 is then asserted (Low) coupling the read value from one of the lines (inverted line in FIG. 5) of the bit line to the output driver, which provides the output data signal 610.

It should be appreciated that the present invention is applicable for use with all types of semiconductor integrated circuit (“IC”) chips. Examples of these IC chips include but are not limited to processors, controllers, chip set components, programmable logic arrays (PLA), and memory chips.

With reference to FIG. 7, one example of a computer system is shown. The depicted system generally comprises a processor 701 that is coupled to a power supply 702 (which may be a battery), a wireless interface 704, and memory 706. It is coupled to the power supply 702 to receive from it power when in operation. It is coupled to the wireless interface 704 and to the memory 706 with separate point-to-point links (or alternatively, bus links) to communicate with the respective components. The wireless interface, which includes an antenna, couples the processor to a client or network. The processor 701 includes at least one cache memory section 703 with an SRAM memory array with write back circuitry according to an embodiment as discussed herein.

While the inventive disclosure has been described in terms of several embodiments, those skilled in the art will recognize that the invention is not limited to the embodiments described, but can be practiced with modification and alteration within the spirit and scope of the appended claims. For example, while the discussed embodiments used bit cell columns with complementary bit line pairs, other embodiments could use different bit line configurations such as those with a single dischargeable bit line, depending upon a particular technology or application. Likewise, the principles discussed herein could apply to current, as well as voltage, mode bit lines and to different types of read/write memory cells including 4T and other SRAM cells.

Moreover, it should be appreciated that example sizes/models/values/ranges may have been given, although the present invention is not limited to the same. As manufacturing techniques (e.g., photolithography) mature over time, it is expected that devices of smaller size could be manufactured. With regard to description of any timing or programming signals, the terms “assertion” and “negation” are used in an intended generic sense. More particularly, such terms are used to avoid confusion when working with a mixture of “active-low” and “active-high” signals, and to represent the fact that the invention is not limited to the illustrated/described signals, but can be implemented with a total/partial reversal of any of the “active-low” and “active-high” signals by a simple change in logic. More specifically, the terms “assert” or “assertion” indicate that a signal is active independent of whether that level is represented by a high or low voltage, while the terms “negate” or “negation” indicate that a signal is inactive. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A circuit, comprising:
a memory array comprising columns of SRAM bit cells, the columns each comprising a bit line and a sense amplifier coupled to the bit line, the sense amplifier to maintain a state in a selected cell of its bit line during a read operation.

2. The circuit of claim 1, in which the SRAM cells are 6T SRAM cells.

3. The circuit of claim 1, in which the sense amplifier is to provide output data indicating a read cell state.

4. The circuit of claim 3, in which the read cell state is to be provided to an output driver.

5. The circuit of claim 4, in which the read cell state is to be selectably provided through a column select gate.

6. The circuit of claim 5, in which the column select gate is part of a multiplexer.

7. The circuit of claim 1, in which the sense amplifier comprises a cross-coupled inverter pair having outputs directly coupled to the bit line.

8. A chip comprising a circuit in accordance with the circuit of claim 1.

9. A chip, comprising:
a memory array comprising cell columns each comprising a bit line, SRAM bit cells controllably coupled to the bit line, and a sense amplifier coupled to the bit line, the sense amplifier to read and maintain a state in a selected cell of its column for a read operation.

10. The chip of claim 9, in which the SRAM cells are 6T SRAM cells.

11. The chip of claim 9, in which the sense amplifier is to provide output data indicating a read cell state.

12. The chip of claim 11, in which the read cell state is to be provided to an output driver.

13. The chip of claim 12, in which the read cell state is to be selectably provided through a column select gate.

14. The chip of claim 13, in which the column select gate is part of a multiplexer.

15. The chip of claim 9, in which the sense amplifier comprises a cross-coupled inverter pair having outputs directly coupled to the bit line.

16. The chip of claim 9, in which the bit line comprises a complementary bit line pair.

17. A computer system comprising a chip in accordance with the chip of claim 9.

18. A system for a computer, comprising:
(a) a microprocessor comprising a memory array with columns of SRAM bit cells, the columns each comprising a bit line and a sense amplifier coupled to the bit line, the sense amplifier to maintain a state in a selected cell of its bit line during a read operation; and
(b) a wireless interface including an antenna communicatively linked to the microprocessor to communicatively link it to a network.

19. The system of claim 18, in which the bit cells are complementary output SRAM cells.

20. The system of claim 18, further comprising a battery power supply controllably coupled to the microprocessor to provide it with supply power.
